(19) United States
(12) Patent Application Publication
(10) Pub. No.: US 2009/0061113 A1
(43) Pub. Date: Mar. 5, 2009

(54) Embedding Metallic Glass with Nanocrystals

(75) Inventors: Lin Shao, College Station, TX (US); Mark Hollander, Los Alamos, NM (US)

Correspondence Address: FISH & RICHARDSON P.C., P.O. BOX 1022, MINNEAPOLIS, MN, 55440-1022, US

(73) Assignee: TEXAS A&M UNIVERSITY SYSTEM, College Station, TX (US)

(21) Appl. No.: 11/951,991

(22) Filed: Dec. 6, 2007

Related U.S. Application Data
(60) Provisional application No. 60/969,533, filed on Aug. 31, 2007.

(51) Int. Cl. C23C 14/30; B05C 5/00

(52) U.S. Cl. 427/596; 118/620

(57) ABSTRACT

The present disclosure is directed to a system and method for embedding metallic glass with nanocrystals. In some implementations, a method includes positioning at least one of metallic glass or a source configured to emit a particle beam such that the metallic glass and the source are proximate. Nanocrystals embedded in the metallic glass are formed by irradiating the metallic glass with the particle beam.

### CLAIM OF PRIORITY

This application claims priority under 35 USC § 119(e) to U.S. Patent Application Ser. No. 60/969,533, filed on Aug. 31, 2007, the entire contents of which are hereby incorporated by reference.

### TECHNICAL FIELD

This disclosure relates to metallic glass and, more particularly, to embedding metallic glass with nanocrystals.

### BACKGROUND

Metallic glasses are amorphous metals including metallic material with a disordered atomic-scale structure, i.e., non-crystalline structure. While metallic material is in a liquid state, the liquid is cooled at a rate fast enough to avoid crystallization thereby forming a metallic glass. The absence of grain boundaries, i.e., the weak spots of crystalline materials, leads to better resistance to wear and corrosion. Indeed, metallic glasses, as compared with conventional metals, can have higher tensile strength, fatigue strength, hardness, axial fatigue, and fracture toughness. In some cases, metallic glass is an alloy rather than a pure metal. When alloys are in a liquid state, the liquid has low free volume and, thus, higher viscosity due to the varying sizes of the different atoms. The higher viscosity assists in forming metallic glasses because the atoms are sufficiently prevented from moving enough to form an ordered lattice.

### SUMMARY

The present disclosure is directed to a system and method for embedding metallic glass with nanocrystals. In some implementations, a method includes positioning at least one of metallic glass or a source configured to emit a particle beam such that the metallic glass and the source are proximate. Nanocrystals embedded in the metallic glass are formed by irradiating the metallic glass with the particle beam.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a block diagram illustrating a processing system for embedding metallic glass with nanocrystals in accordance with some implementations of the present disclosure;

FIGS. 2A-C are graphs illustrating example implantation processes for embedding metallic glass with nanocrytals. The metallic glass is coated on another materials and projected range of the particle beam is within the metallic glass.

FIG. 3A is a graph illustrating hardness of an unirradiated and irradiated metallic glass as a function of depth;

FIG. 3B is a graph illustrating indentation hardness of the unirradiated and irradiated the metallic glass;

FIG. 3C is a graph illustrating changes in hardness between the unirradiated and irradiated the metallic glass;

FIG. 3D is a graph illustrating nuclear stopping and electronic stopping as a function of penetration depth in the metallic glass;

FIG. 3E is an example high resolution image of the irradiated metallic glass; and

FIG. 4 is a diagram illustrating an example method for embedding metallic glass with nanocrystals.

Like reference symbols in the various drawings indicate like elements.

### DETAILED DESCRIPTION

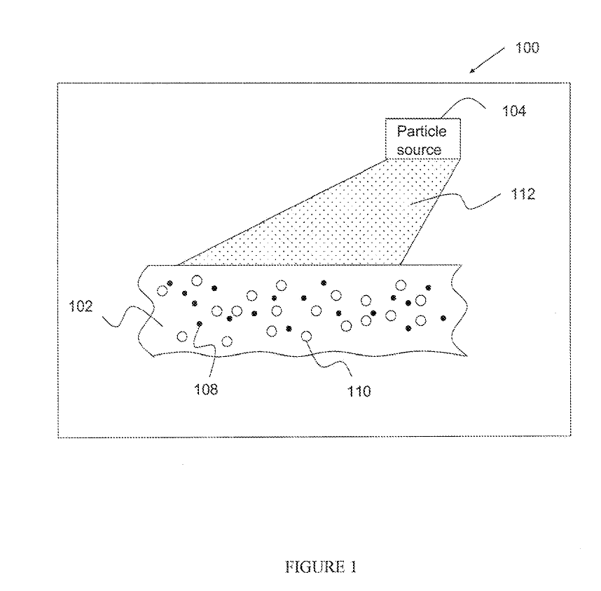

FIG. 1 is a processing system 100 for embedding metallic glass with nanocrystals in accordance with some implementations in the present disclosure. Nanocrystals may include structures on the nanometer scale formed from one or more components of the metallic glass. For example, the nanocrystals may be substantially spherical with a diameter between 1 nanometer (nm) to 100 nm (e.g., 2 to 3 nm). In general, metal glasses include metallic material (e.g., Cu₅₀Zr₄₅Ti₅) having an amorphous atomic structure. In some implementations, the system 100 can embed nanocrystals in a metallic glass by irradiating metallic glass with one or more particle beams independent of thermally annealing the metallic glass to form the nanocrystals. For example, the system 100 may irradiate metallic glass with an ion beam while maintaining an increase in temperature to 50° C. or less. By embedding the nanocrystals, the system 100 may maximize, enhance or otherwise improve one or more physical properties of the metallic glass. For example, the metallic glass embedded with nanocrystals may increase ductility and/or hardness. In addition, the system 100 may embed the metallic glass with air pockets such as air bubbles. By embedding metallic glass with both nanocrystals and air bubbles, the system 100 may improve one or more physical properties of the metallic glass while reducing the density of the metallic glass. In some implementations, the system 100 can reduce the density of a metallic glass embedded with nanocrystals by 50% or more.

At a high level, the system 100 can, in some implementations, include a substrate of metallic glass 102 and a particle source 104 where at least the metallic glass 102 is enclosed in a vacuum chamber 106. In some implementations, the system 100 includes a cooling element 111 to substantially maintain the metallic glass 102 below, at or proximate room temperature during irradiation. The vacuum chamber 106 may produce a vacuum of 1×10⁻⁷ Torrs or less. In the case of some particles (e.g., electrons, neutrons), the vacuum chamber 106 can remain at atmospheric pressure during irradiation. The particle source 104 irradiates the metallic glass 102 with a particle beam 112 to generate or otherwise form nanocrystals 108 in the metallic glass 102. In some implementations, the particle beam 112 can generate or otherwise form pockets 110 in the metallic glass 102.

Turning to a detailed description of the elements, the metallic glass 102 includes solidified metallic material substantially having an amorphous atomic structure. For example, the metallic glass 102 may have been formed by rapidly quenching one or more metals in a liquid state. In doing so, the metallic glass 102 is substantially absent of grain boundaries. The metallic glass 102 may be formed using any other suitable process such as physical vapor deposition, solid-state reaction, ion irradiation, melt spinning, and/or mechanical alloying. In some implementations, the metallic glass 102 may include one or more of the following: zirconium, palladium, iron, titanium, copper, magnesium, zirconium, nickel, beryllium, and/or others. For example, the metallic glass 102 may be Cu₅₀Zr₄₅Ti₅. In illustrated implementation, the metallic glass 102 includes nanocrystals 108 and pockets 110 resulting from irradiation. The nanocrystals 108 include nanometer-sized structures formed in the metallic glass 102. For example, the nanocrystals 108 may be 1 nm to 100 nm in at least one dimension. In some implementations, the nanocrystals 108 can be sub-nanometer sizes. The nanocrystals 108 may include one or more of the following shapes: plates, spheres, cylinders, tubes, fibers, 3D structures, segments, rings, amorphous, and/or any other shapes. For example, a subset of the nanocrystals 108 can, in some implementations, be substantially spherical with diameters between 2 to 3 nm. In some implementations, the nanocrystals 108 are formed from one or more of the constituents of the metallic glass 102. In some implementations, the nanocrystals 108 are substantially uniformly distributed in the metallic glass 108. The pockets 110 include vacant spaces in the metallic glass 102. For example, the pockets 110 may be air bubbles formed in the metallic glass 102. In some implementations, the pockets 110 are substantially spherical with a nanometer-size diameter (e.g., 10 nm). As mentioned above, when the metallic glass 102 includes both the nanocrystals 108 and the pockets 110, the system 100 may improve one or more physical properties of the metallic glass 102 while reducing the density.

The particle source 104 can include any software, hardware, and/or firmware configured to provide particles to the vacuum chamber 106. For example, the particle source 104 may generate, emit, or otherwise irradiate particles to the vacuum chamber 106 thereby forming a particle beam 112. The emitted particles may include one or more of the following: ions, electrons, neutrons, atoms, and/or others. For example, the particle beam 112 may include He ions. In some implementations, the particle beam 112 includes one or more noble gases (e.g., Xenon). In some implementations, the particle beam 112 has an energy between 1 keV and 10 MeV (e.g., 140 keV). The particle beam 112 may be emitted for a short burst, continuously, intermittently, and/or in accordance with other patterns. In some implementations, the energy of the particle beam 112 may be increase over a period of time such as ramped up over a period of time. The particle beam 112 can, in some implementations, have fluencies between 1×10¹⁴ particles/cm² and 1×10¹⁸ particles/cm² (e.g., 1.7×10¹⁷ particles/cm²). In general, the particle beam 112 may include particles with one or more masses, energies, radiation dosages, and/or radiation temperatures. In some implementations, the vacuum chamber may include a cooling element (e.g., liquid N2 cooling element) to substantially maintain the temperature of the samples at or near room temperature (e.g., 50° C. or less).

The energetic particles may be produced by using the techniques of plasma immersion ion implantation or traditional ion implantation in which the particles are well purified and scanned to achieve a good uniformity. Typical ion implantation equipment consists of an ion source, where ions of the desired element are produced, an accelerator, where the ions are electrostatically accelerated to the desired energy and the target chamber having the materials to be bombarded (not illustrated). At least one magnet may be used to purify the ions.

The energy of the ions as well as the ions species and the composition of the target materials may determine the depth of the ions in the target. During ion bombardment, ions may transfer their momentum to the target atoms through two mechanisms: the interaction with target nucleus (to cause displacement and/or damage cascades) and the interaction with target electrons (to excite the electrons). The energy loss rate per unit length due to the above two mechanism may be called nuclear stopping and electronic stopping, respectively. Both stopping powers may be dependent on ion energies. In some implementations, the nuclear stopping can more efficiently cause nanocrsytal formation. In some instances, implantation parameters may need to be adjusted to maximize the effects.

Both nuclear stopping and electronic stopping powers may contribute to the slowing down of the particles in metallic glasses. The final projected range of particles can, in some implementations, be well controlled by ion energies.

The thickness of metallic glasses is often limited to a few centimeters. For the application as structural materials, the metallic glasses may be coated on other materials (e.g., stainless steels). To improve adhesion with other materials, the projected range of ions may be controlled to be at or beyond the interface. In this example, the bonding between the coated metallic glasses and the materials underneath the glasses may be strengthened by ion mixing. In some implementations, the ion mixing can be a consequence of interdiffusion of atoms cross the interface caused by ion bombardments.

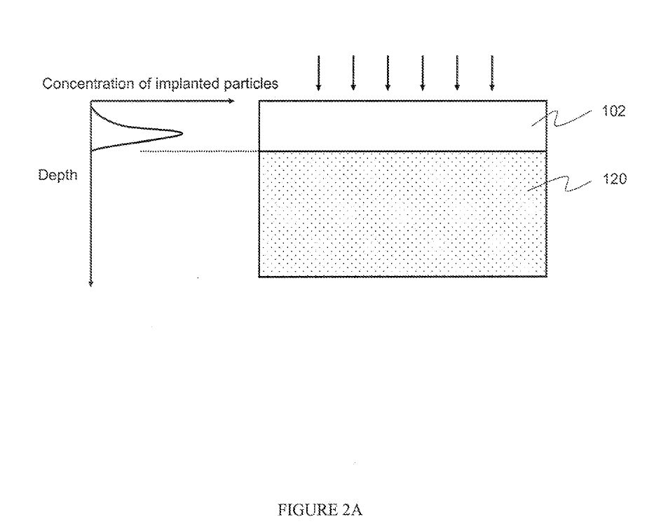

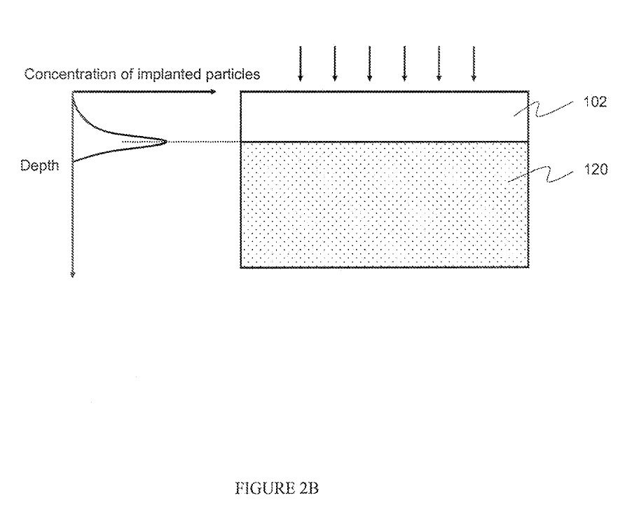

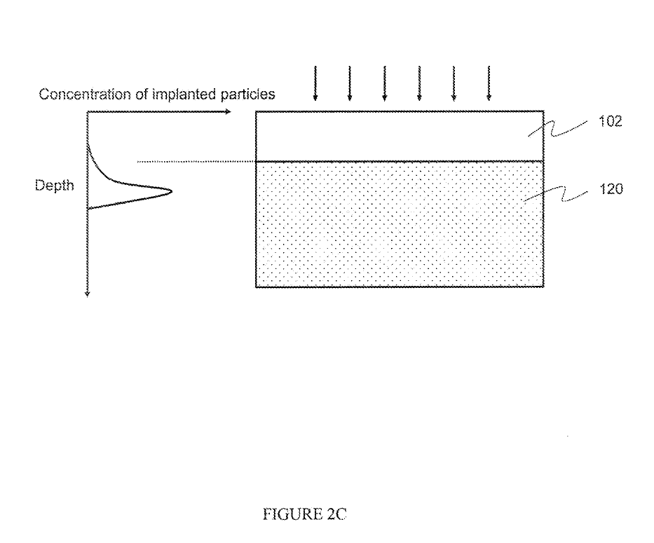

FIG. 2A-2C illustrate three embodiments for embedding nanocrystals by using different ion energies to located ions at different locations. In FIG. 2A, ions are controlled to be within the metallic glasses. In FIG. 2B, ions are located at the interface between the metallic glasses and/or other structural materials. In FIG. 2C, ions are located at a depth beyond the interface. The underneath materials 120 include, but not limited to, ferritic steel, martensitic steel, austenitic steel and/or other duplex stainless steels.

In FIGS. 2A-C, the particle beams are monoenergetic beams. In some implementations, energies of the particle beam may be changed during the ion implantation. In this case, at least part of the particle beam may have energies high enough to penetrate the interface to induce significant ion mixing. It is well known that the maximum ion mixing occurs when the nuclear stopping powers of incident particles reaches the maximum. The maximum nuclear stopping usually occurs when particles slow down to a few keV (dependent on particle species and/or target atoms), an energy region very close to their final stopping in the materials. A maximum ion mixing may be reached when the projected range of particles are slightly deeper than the interface.

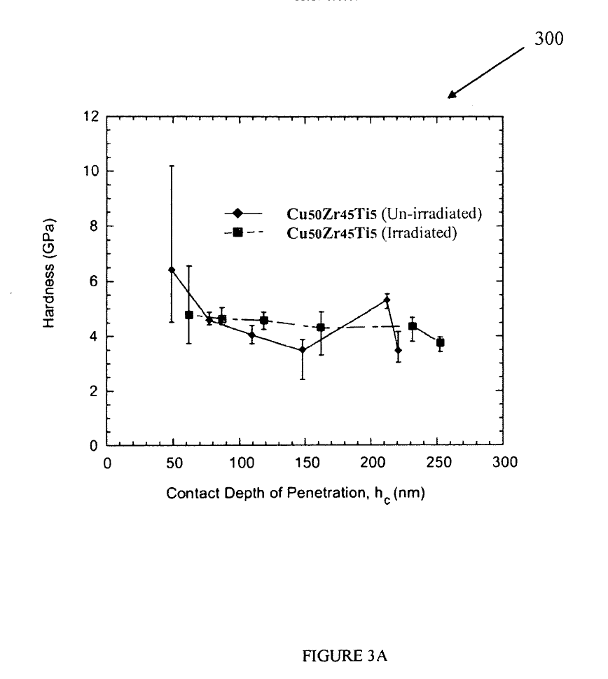

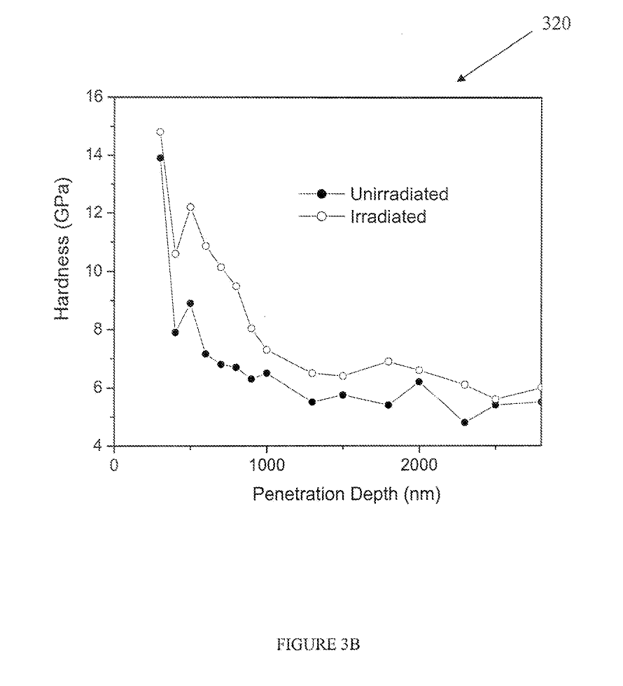

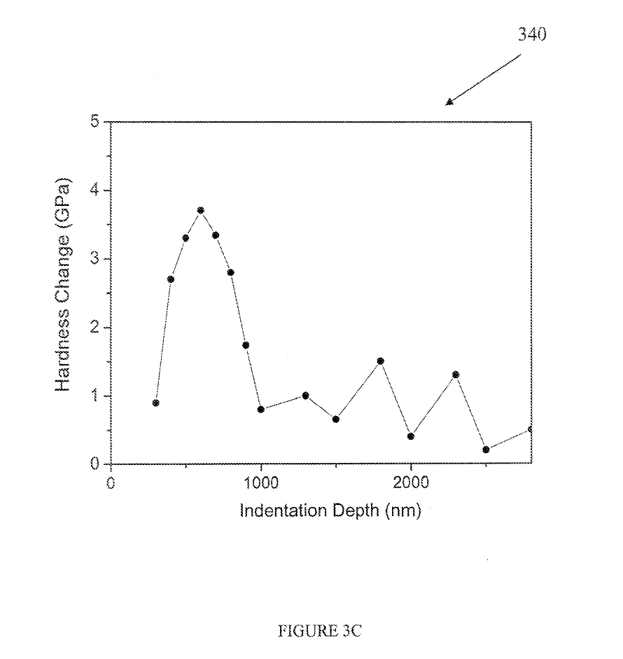

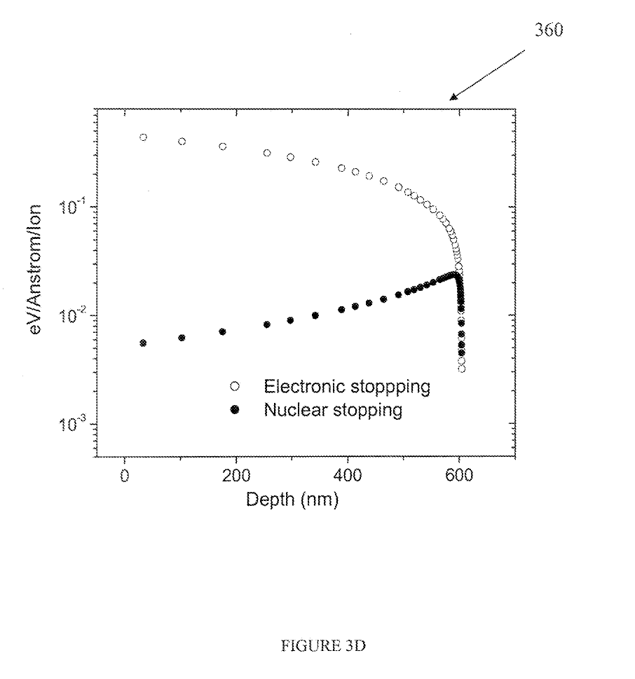

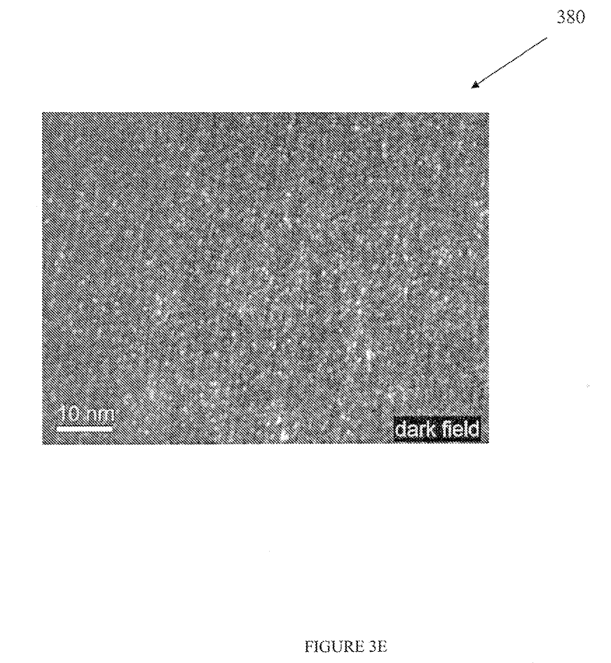

FIGS. 3A-3E illustrate graphs 300, 320, 340, and 360 and image 380 associated with embedding nanocrystals in a Cu₅₀Zr₄₅Ti₅ (CZT) alloy, a metallic glass. The following description is for example purposes only. The system 100 may uses some, all, and/or different processes for forming nanocrystals in the CZT alloy and/or other metallic glasses.

Initially, the CZT alloy was prepared by melting a mixture of pure Cu, Zr, and Ti in an argon atmosphere. The liquid was rapidly solidified to form ribbon-shaped samples, 1.5 millimeters (mm) in width by 20 micrometers (microns) in thickness. After the samples were cut into pieces, the metallic glass was irradiated at room temperature with 140 keV He ions having a fleunce of 1.7×10¹⁷ atoms/cm². During the beam exposure, beam heating was maintained at 50° C. or less. After forming nanocrystals, the specimens, due to the width and curvature, were mounted to microscope slides using wax. Several nanoindentation tests were performed on the unirradiated and irradiated samples to determine the distribution of hardness as a function of depth. In addition, a Fischerscope HM200 with Vicker's indenter was used to perform microindentation. Using the results of the tests, the irradiation induced hardness changes were determined by comparing data from the unirradiated and irradiated samples.

Referring FIG. 3A, the graph 300 illustrates hardness of the unirradiated and irradiated Cu50Zr45Ti5 as a function of depth. During these tests, a set of 5 loads were initially used to determine the distribution of hardness in the samples. An additional load was added (10,000 μN) to obtain the greatest possible depth for the samples. Each data point in the graph 300 represents the average hardness value for five indentation measurements at each load, and the error bars represent the maximum and the minimum values. As indicated in the graph 300, no significant changes in the hardness from the surface up to 250 nm was identified. In some cases, these tests can be sensitive to surface roughness. Accordingly, an atomic force microscope was used to characterize the surface roughness. The roughness over a 1 μm×1 μm area was about 0.8 nm for the unirradiated sample and about 1.2 for the irradiated sample, so the hardness tests were reliable in light of the relatively smooth surfaces for both samples.

Referring to FIG. 3B, the graph 320 illustrates hardness of the unirradiated and irradiated metallic glass using microindentation. As indicated in the graph 320, the hardness at a depth of about 600 nm increases from 9 GPa for the unirradiated samples to 12 GPa for the irradiated samples, and the hardness changes become smaller at depths beyond 1000 nm. In comparison to nanoindentation tests, the hardness data in the microindentation may be unreliable for depths shallower than about 200 nm. In short, the hardness changes at the depth of about 600 nm indicate a significant mechanical property change in the irradiated metallic glass.

Referring to FIG. 3C, the graph 340 illustrates changes in hardness between the unirradiated and irradiated metallic glass derived from data illustrated in FIG. 3D. As indicated in the graph 340, the hardness enhancement in the irradiated samples reaches a peak at a depth of about 600 nm. As for depth levels beyond 1000 nm, the hardness changes approach the noise level as indicated by the oscillations at different depths. In addition, the trend of the curve from 300 nm to 600 nm indicates that hardness enhancement may be negligible for depths less than 300 nm.

Referring to FIG. 3D, the graph 360 illustrates nuclear stopping and electronic stopping as a function of penetration depth in the metallic glass. As is known in the art, both nuclear and electron stopping can contribute to ion stopping in solids. In regards to nuclear stopping, ions can lose energy by collisions with target nucleus. In regards to electron stopping, ions can lose energy by collisions with target electrons. The extent of the contribution from these mechanisms may be based on the velocity and/or charge of the ions. As indicated in the graph 360, electron stopping decreases with increasing depth while nuclear stopping is peaked at a depth of about 600 nm, which corresponds to the projected range of the 140 keV He ions in the metallic glass. Both the nuclear stopping depth and hardness changes peak at about 600 nm, which suggest that hardness enhancement may be due to nuclear stopping rather than electron stopping. In this case, the hardness changes may be related to damage cascade formation associated with nuclear stopping.

FIG. 3E is an example high resolution image 380 of the irradiated metallic glass. In particular, the image 380 is a dark-field Tunneling Electron Microscope (TEM) image of the metallic glass including nanocrystals 382. As is known in the art, TEM, in dark-field mode, detects diffraction or scattered electrons. The bright spots in the image 380 represent the nanocrystals 382 formed in the irradiated metallic glass, which are about 1-2 nm in diameter. In some implementations, the yield strength may increase as a function of volume fraction of nanocrystals 382.

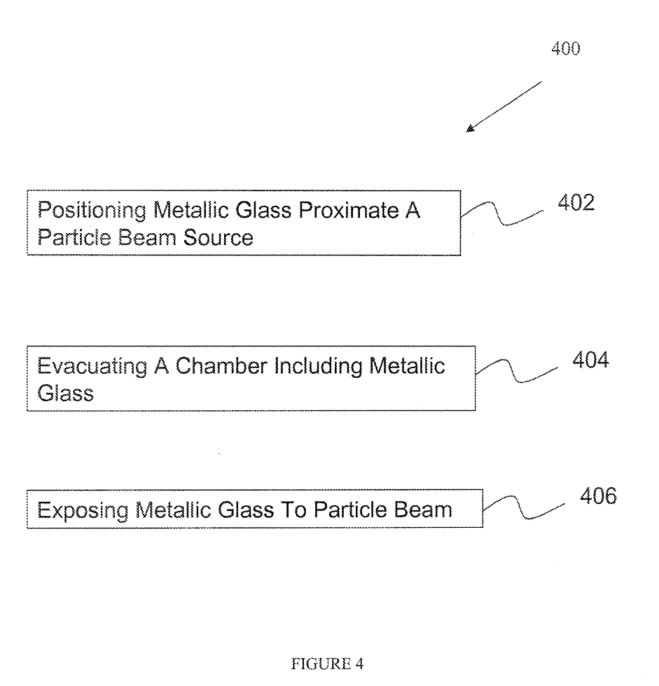

FIG. 4 is a flowchart illustrating an example method 400 for manufacturing metallic glass embedded with nanocrystals in accordance with some implementations of the present disclosure. Generally, the method 400 describes irradiating metallic glass to a particle beam to form embedded nanocrystals. The method 400 contemplates using any appropriate combination and arrangement of logical elements implementing some or all of the described functionality.

Method 400 begins at step 402 where a metallic glass is positioned proximate a source of particle beams. The proximity may be based on fleunce, energy, particle type, and/or other parameters. As mentioned above, the metallic glass can be formed by quenching a liquid including metallic material, evaporation (e.g., thin film), and/or using other processes. In some implementations, the metallic glass can be formed on a substrate, an apparatus, and/or other elements. At step 404, a chamber including the metallic glass is evacuated. For example, the chamber may be evacuated to 1×10⁻⁷ Torrs. Next, at step 406, the metallic glass is exposed to a particle beam to form nanocrystals embedded in the metallic glass. For example, the metallic glass may be exposed to an ion beam of noble gas (e.g., Xenon) to form nanocrystals. In this example, the ion beam of noble gas may form air pockets in the metallic glass. In some implementations, forming both nanocrystals and gas-filled pockets in the metallic glass may improve one or more physical properties (e.g., ductility, hardness) while decreasing the density (e.g., 50%). In some implementations, temperature increases may be maintained below a certain threshold by, form example, adjusting beam parameters, actively cooling the metallic glass, and/or other processes.

Although this disclosure has been described in terms of certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure.

What is claimed is:

1. A method for forming nanocrystals:
positioning at least one of metallic glass or a source configured to emit a particle beam incident the metallic glass; and
forming nanocrystals embedded in the metallic glass by irradiating the metallic glass with the particle beam.

2. The method of claim 1, further comprising evacuating a chamber including the metallic glass below a specified pressure prior to irradiating in the evacuated chamber.

3. The method of claim 2, wherein the specified pressure is 1×10⁻⁷ Torrs or less.

4. The method of claim 1, wherein positioning at least one of metallic glass or a source comprises positioning the metallic glass proximate the source.

5. The method of claim 1 wherein the metallic glass includes a plurality of metals.

6. The method of claim 1, wherein the particle beam comprises at least one of ions, electrons, or neutrons.

7. The method of claim 1, wherein the particle beam comprises one or more noble gases.

8. The method of claim 7, further comprising forming gas pockets in the metallic glass during the irradiation with the one or more noble gases.

9. The method of claim 1, wherein the particle beam includes an energy between 1.0 keV to 10 MeV.

10. The method of claim 1, wherein the particle beam has a fleunce between 1×10¹⁴ particles/cm² and 1×10¹⁹ particles/cm².

11. The method of claim 1, further comprising maintaining a temperature increase in the metallic glass during irradiation to 200° C. or less.

12. A system for embedding nanocrystals, comprising:
a particle source configured to emit particles in accordance with one or more parameters; and
metallic glass configured to form nanocrystals in response to at least irradiation by the particles.

13. The system of claim 12, further comprising a vacuum chamber configured to enclose at least the metallic glass and maintain a vacuum in the chamber at below a specified pressure during irradiation of the metallic glass.

14. The system of claim 13, wherein the specified pressure is 1×10⁻⁷ Torrs or less.

15. The system of claim 12, wherein the metallic glass includes a plurality of metals.

16. The system of claim 12, wherein the particle beam comprises at least one of ions, electrons, or neutrons.

17. The system of claim 12, wherein the particle beam comprises one or more noble gases.

18. The system of claim 17, wherein the particle beam forms air pockets in the metallic glass during the irradiation with the one or more noble gases.

19. The system of claim 12, wherein the particle beam includes an energy between 1.0 keV to 10 MeV.

20. The system of claim 12, wherein the particle beam has a fleunce between 1×10¹⁴ particles/cm² and 1×10¹⁹ particles/cm².

21. The system of claim 12, further comprising a cooling element configured to maintain a temperature increase in the metallic glass during irradiation to 200° C. or less.

22. The system of claim 12, wherein the emitted particles comprises at least one or more constituents of the metallic glass.

23. A method for forming nanocrystals:
coating one layer of metallic glass on a first structure to form a second structure; and
forming nanocrystals embedded in the metallic glass by irradiation the second structure with a particle beam.

24. The method of claim 23, wherein projected ranges of at least a subset of the particles is greater than an interface between the metallic glass and the first structure.

25. The method of claim 24, wherein substantially all of the particles projected ranges greater than the interface between the metallic glasses and the first structure.
